(19) United States
(12) Patent Application Publication
(10) Pub. No.: US 2025/0118577 A1
(43) Pub. Date: Apr. 10, 2025

(54) CERAMIC RF RETURN KIT DESIGN

(71) Applicant: Applied Materials, Inc., Santa Clara, CA (US)

(72) Inventors: Vellaichamy Nagappan, Ramanathapuram (IN); Viren Kalsekar, Mountain View, CA (US); Vinay K. Prabhakar, Fremont, CA (US); Dharma Ratnam Srichurnam, Hyderabad (IN); Satish Radhakrishnan, San Jose, CA (US); Siva Chandrasekar, Hosur (IN); Sumit Subhash Singh, Mumbai (IN); Pratap Chandran, Bengaluru (IN)

(73) Assignee: Applied Materials, Inc., Santa Clara, CA (US)

(21) Appl. No.: 18/484,232

(22) Filed: Oct. 10, 2023

(51) Int. Cl. H01L 21/67; H01L 21/677

(52) U.S. Cl. CPC H01L 21/6719; H01L 21/67069; H01L 21/67098; H01L 21/67742

(57) ABSTRACT

Exemplary semiconductor processing systems may include a chamber body having a bottom plate. The systems may include a substrate support disposed within the chamber body. The substrate support may include a support plate and a shaft. The shaft may include a cooling hub that extends through the bottom plate. The shaft may include a ground shaft that is seated atop the cooling hub. The ground shaft may include a ceramic material. The systems may include an inner isolator coupled with a bottom of the support plate. The inner isolator may define an aperture therethrough that receives the shaft. The systems may include an outer isolator that is seated atop the inner isolator. Each of the inner isolator and the outer isolator may include a ceramic material.

### TECHNICAL FIELD

The present technology relates to semiconductor processing equipment. More specifically, the present technology relates to semiconductor chamber components and methods of substrate processing.

### BACKGROUND

Temperature non-uniformity across the substrate during substrate processing can lead to uneven and inconsistent substrates. Such non-uniformity may arise when a faceplate opposite a pedestal supporting the substrate undergoes sublimation along its face. This sublimation can lead to temperature non-uniformity across the substrate during processing. In order to avoid this sublimation, it would be beneficial to ensure that the faceplate is properly purged during substrate processing. However, the flow rate required to purge the faceplate with traditional substrate processing system designs are not enough to prevent faceplate sublimation.

Additionally, contaminants within semiconductor substrates can adversely affect the performance and quality of the substrate. As such, substrate processing environments are directed to minimizing the risk of contaminants entering the substrates during processing, which may arise from the components of the semiconductor processing equipment itself. For example, stainless steel components can react with purge gases, such as nitrogen trifluoride, to form metal contaminants during corrosion that may invade the substrates during processing. While these stainless steel components may be given a coating to help shield the stainless steel material from reacting to the purge gases, at high enough temperatures (e.g., the temperatures at which substrates are processed, such as 400° C. or higher), such coating can flake off and leave the stainless steel material exposed for oxidation and corrosion. Such heat can additionally exacerbate this issue by increasing the rate of oxidation and corrosion of the exposed stainless steel components, thus further increasing the risk that contaminants enter the substrate processing environment.

As such, it would be additionally beneficial to minimize the risk of stainless steel components within substrate processing environments from reacting with purge gases to form contaminants.

### SUMMARY

Exemplary semiconductor processing systems may include a chamber body having a bottom plate. The systems may include a substrate support disposed within the chamber body. The substrate support may include a support plate and a shaft. The shaft may include a cooling hub that extends through the bottom plate. The shaft may include a ground shaft that is seated atop the cooling hub. The ground shaft may include a ceramic material. The systems may include an inner isolator coupled with a bottom of the support plate. The inner isolator may define an aperture therethrough that receives the shaft. The systems may include an outer isolator that is seated atop the inner isolator. Each of the inner isolator and the outer isolator may include a ceramic material.

In some embodiments, the systems may include a lower lid plate seated atop the chamber body. The systems may include a thermal choke plate seated atop the lower lid plate. The systems may include a pumping liner seated atop the thermal choke plate. The systems may include a faceplate seated atop the pumping liner, the faceplate defining a processing region from above. The systems may include a bellow that couples a bottom surface of the bottom plate with a bottom end of the cooling hub. The faceplate, the pumping liner, the thermal choke plate, the lower lid plate, the chamber body, the bottom plate, the bellow, and the cooling hub may form a portion of an RF return path. The systems may include a plurality of RF gaskets. Each of the plurality of RF gaskets may be disposed between two adjacent components that make up the RF return path. The thermal choke plate may define a purge inlet, a purge channel, and a number of purge outlets that deliver a purge gas to an interior of the chamber body. There may be no exposed stainless steel within an interior of the chamber body.

Some embodiments of the present invention may encompass semiconductor processing systems that may include a chamber body having a bottom plate. The systems may include a substrate support disposed within the chamber body. The substrate support may include a support plate and a shaft. The shaft may include a cooling hub that extends through the bottom plate. A top surface of the cooling hub may define a plurality of dimples. The shaft may include a ground shaft that is seated atop the plurality of dimples. The ground shaft may include a ceramic material. The systems may include an inner isolator coupled with a bottom of the support plate. The inner isolator may define an aperture therethrough that receives the shaft. The systems may include an outer isolator that is seated atop the inner isolator. Each of the inner isolator and the outer isolator may include a ceramic material.

In some embodiments, the systems may include a plurality of lift pin assemblies. Each lift pin assembly may include a standoff that is seated atop the bottom plate. The standoff may include a chamber-compatible material. Each lift pin assembly may include a lift pin seated atop the standoff. The chamber-compatible material may include aluminum. A bottom end the standoff may define a central bore. The bottom plate may define a recess. A first insert may be received within the central bore. A second insert may be received within the recess. A threaded stud may be inserted within both the first insert and the second insert to secure the standoff to the bottom plate. The first insert, the second insert, and the threaded stud may include stainless steel. The systems may include a thermal choke plate seated atop the chamber body. The thermal choke plate may define a purge inlet, a purge channel, and a number of purge outlets that deliver a purge gas to an interior of the chamber body. The purge channel may include a number of linear segments that intersect one another.

Some embodiments of the present invention may encompass semiconductor processing systems that may include a chamber body having a bottom plate. The systems may include a substrate support disposed within the chamber body. The substrate support may include a support plate and a shaft. The shaft may include a cooling hub that extends through the bottom plate. The shaft may include a ground shaft that is seated atop the cooling hub. The ground shaft may include a ceramic material. The systems may include a bellow that couples a bottom surface of the bottom plate with a bottom end of the cooling hub. The systems may include an inner isolator coupled with a bottom of the support plate. The inner isolator may define an aperture therethrough that receives the shaft. The systems may include an outer isolator that is seated atop the inner isolator. Each of the inner isolator and the outer isolator may include a ceramic material.

In some embodiments, a bottom end of the cooling hub may include a lower flange. An upper end of the bellow may be coupled with the bottom surface of the bottom plate. A lower end of the bellow may be coupled with an upper surface of the lower flange. The bellow may expand and contract as the substrate support is translated within the chamber body. The systems may include a first RF gasket disposed between the bottom surface of the bottom plate and the upper end of the bellow. The systems may include a second RF gasket disposed between the lower end of the bellow and the upper surface of the lower flange.

### BRIEF DESCRIPTION OF THE DRAWINGS

A further understanding of the nature and advantages of the disclosed technology may be realized by reference to the remaining portions of the specification and the drawings.

FIG. 1A shows a schematic top view of an exemplary processing tool according to some embodiments of the present technology.

FIG. 1B shows a schematic partial cross-sectional view of an exemplary processing system according to some embodiments of the present technology.

FIG. 2 shows a schematic isometric view of a transfer section of an exemplary substrate processing system according to some embodiments of the present technology.

FIG. 3 shows a cross-sectional view of an exemplary system arrangement of an exemplary substrate processing system according to some embodiments of the present technology.

FIG. 4A shows a top isometric view of a choke plate of the substrate processing system of FIG. 3.

FIG. 4B shows a bottom isometric view of a choke plate of the substrate processing system of FIG. 3.

FIG. 4C shows a cross-sectional view along section view A-A of the choke plate of FIG. 4A.

FIG. 4D shows a cross-sectional view along section view B-B of the choke plate of FIG. 4A.

FIG. 4E shows a cross-sectional view along section view C-C of the choke plate of FIG. 4A.

FIG. 4F shows a cross-sectional top plan view of the choke plate of FIG. 4A.

FIG. 5 shows a top isometric view of the inner and outer isolators of the substrate processing system of FIG. 3.

FIG. 5A shows a cross-section of the inner and outer isolators of FIG. 5.

FIG. 5B illustrates a bottom isometric view of the outer isolator of FIG. 5.

FIG. 6 shows a detailed view of a lift pin standoff according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

However, as additional process locations are added, accessing these locations from a central robot may no longer be feasible without additional transfer capabilities at each location. Some conventional technologies may include wafer carriers on which the substrates remain seated during transition. However, wafer carriers may contribute to thermal non-uniformity and particle contamination on substrates. The present technology overcomes these issues by incorporating a transfer section vertically aligned with processing chamber regions and a carousel or transfer apparatus that may operate in concert with a central robot to access additional wafer positions.

Additionally, conventional faceplates may experience sublimation of that may lead to temperature uniformity issues across the faceplate. To alleviate these issues conventional systems incorporate purge gas that is introduced into the chamber from a bottom of the chamber. However, such purge gas designs suffer from several drawbacks. For example, the bottom purge may introduce metal contamination on wafer as the purge gas may break off oxidized portions of stainless steel chamber components including a grounding plate at the bottom of the pedestal. Additionally, in multi-chamber systems that share a single transfer volume (but that have separate process/reaction volumes for each chamber) the introduction of purge gas from the bottom of the chamber (e.g., within the shared transfer volume) may cause large temperature differences between the transfer volume and reactor volume. Conventional chambers may also have small diffusion volumes, which may require higher flow rates of purge gas to adequately purge the chamber.

The present technology addresses these issues by providing thermal choke plates that introduce a purge gas into the chamber within the reaction volume. This may help reduce the pressure delta between the reaction volume and transfer volume, as well as reduce the volume of purge gas needed to purge the chamber. The introduction of purge gas within the reaction volume may also improve the temperature uniformity during hot-leveling of the pedestal. The choke plate height may also be increased, which may provide a longer and more uniform diffusion surface alongside the pedestal, and may help prevent the sublimation of the faceplate. Embodiments may utilize a multi-piece isolator to help thermally isolate the ground plate from high temperatures of the pedestal proximate the substrate support surface.

Although the remaining disclosure will routinely identify specific structures, such as four-position transfer regions, for which the present structures and methods may be employed, it will be readily understood that the systems and methods are equally applicable to any number of structures and devices that may benefit from the transfer capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

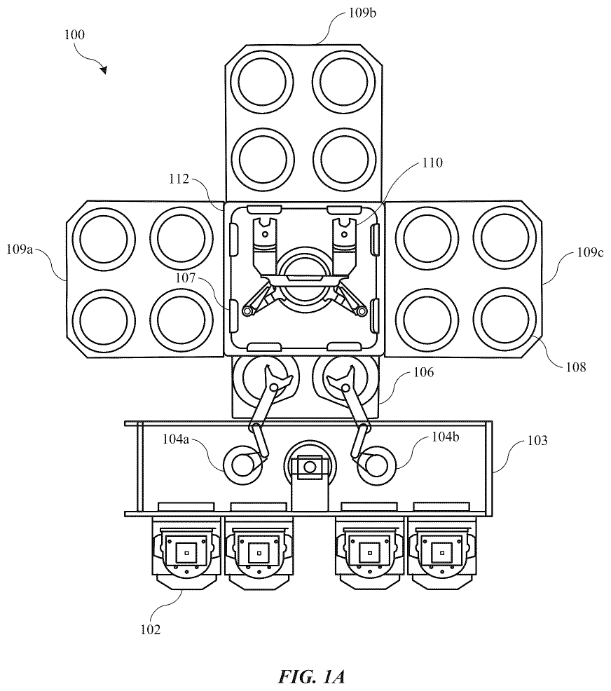

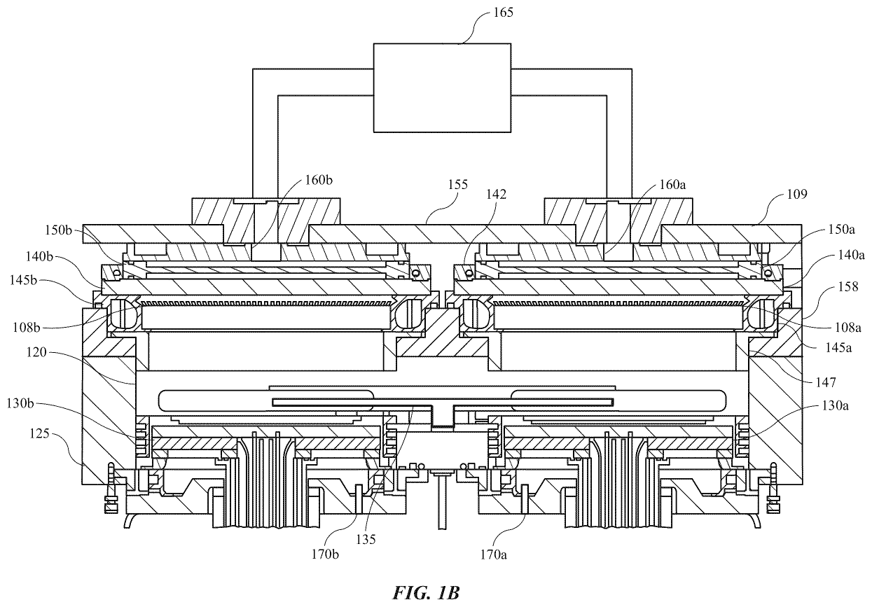

FIG. 1A shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

FIG. 1B shows a schematic cross-sectional elevation view of one embodiment of an exemplary processing tool, such as through a chamber system, according to some embodiments of the present technology. FIG. 1B may illustrate a cross-sectional view through any two adjacent processing regions 108 in any quad section 109. The elevation view may illustrate the configuration or fluid coupling of one or more processing regions 108 with a transfer region 120. For example, a continuous transfer region 120 may be defined by a transfer region housing 125. The housing may define an open interior volume in which a number of substrate supports 130 may be disposed. For example, as illustrated in FIG. 1A, exemplary processing systems may include four or more, including a plurality of substrate supports 130 distributed within the housing about the transfer region. The substrate supports may be pedestals as illustrated, although a number of other configurations may also be used. In some embodiments the pedestals may be vertically translatable between the transfer region 120 and the processing regions overlying the transfer region. The substrate supports may be vertically translatable along a central axis of the substrate support along a path between a first position and a second position within the chamber system. Accordingly, in some embodiments each substrate support 130 may be axially aligned with an overlying processing region 108 defined by one or more chamber components.

The open transfer region may afford the ability of a transfer apparatus 135, such as a carousel, to engage and move substrates, such as rotationally, between the various substrate supports. The transfer apparatus 135 may be rotatable about a central axis. This may allow substrates to be positioned for processing within any of the processing regions 108 within the processing system. The transfer apparatus 135 may include one or more end effectors that may engage substrates from above, below, or may engage exterior edges of the substrates for movement about the substrate supports. The transfer apparatus may receive substrates from a transfer chamber robot, such as robot 110 described previously. The transfer apparatus may then rotate substrates to alternate substrate supports to facilitate delivery of additional substrates.

Once positioned and awaiting processing, the transfer apparatus may position the end effectors or arms between substrate supports, which may allow the substrate supports to be raised past the transfer apparatus 135 and deliver the substrates into the processing regions 108, which may be vertically offset from the transfer region. For example, and as illustrated, substrate support 130a may deliver a substrate into processing region 108a, while substrate support 130b may deliver a substrate into processing region 108b. This may occur with the other two substrate supports and processing regions, as well as with additional substrate supports and processing regions in embodiments for which additional processing regions are included. In this configuration, the substrate supports may at least partially define a processing region 108 from below when operationally engaged for processing substrates, such as in the second position, and the processing regions may be axially aligned with an associated substrate support. The processing regions may be defined from above by a faceplate 140, as well as other lid stack components. In some embodiments, each processing region may have individual lid stack components, although in some embodiments components may accommodate multiple processing regions 108. Based on this configuration, in some embodiments each processing region 108 may be fluidly coupled with the transfer region, while being fluidly isolated from above from each other processing region within the chamber system or quad section.

In some embodiments the faceplate 140 may operate as an electrode of the system for producing a local plasma within the processing region 108. As illustrated, each processing region may utilize or incorporate a separate faceplate. For example, faceplate 140a may be included to define from above processing region 108a, and faceplate 140b may be included to define from above processing region 108b. In some embodiments the substrate support may operate as the companion electrode for generating a capacitively-coupled plasma between the faceplate and the substrate support. The faceplate may be heated in some embodiments with a heater 142 extending about the faceplate. A pumping liner 145 may at least partially define the processing region 108 radially, or laterally depending on the volume geometry. Again, separate pumping liners may be utilized for each processing region. For example, pumping liner 145a may at least partially radially define processing region 108a, and pumping liner 145b may at least partially radially define processing region 108b. The pumping liners 145 may be seated on a choke plate 147, which may control heat distribution from the lid stack to the cooled chamber body. A blocker plate 150 may be positioned between a lid 155 and the faceplate 140 in embodiments, and again separate blocker plates may be included to facilitate fluid distribution within each processing region. For example, blocker plate 150a may be included for distribution towards processing region 108a, and blocker plate 150b may be included for distribution towards processing region 108b.

Lid 155 may be a separate component for each processing region, or may include one or more common aspects. Lid 155 may be one of two separate lid plates of the system in some embodiments. For example, a first lid plate 158 may be seated over transfer region housing 125. The transfer region housing may define an open volume, and first lid plate 158 may include a number of apertures through the lid plate separating the overlying volume into specific processing regions. In some embodiments, such as illustrated, lid 155 may be a second lid plate, and may be a single component defining multiple apertures 160 for fluid delivery to individual processing regions. For example, lid 155 may define a first aperture 160a for fluid delivery to processing region 108a, and lid 155 may define a second aperture 160b for fluid delivery to processing region 108b. Additional apertures may be defined for additional processing regions within each section when included. In some embodiments, each quad section 109—or multi-processing-region section that may accommodate more or less than four substrates, may include one or more remote plasma units 165 for delivering plasma effluents into the processing chamber. In some embodiments individual plasma units may be incorporated for each chamber processing region, although in some embodiments fewer remote plasma units may be used. For example, as illustrated a single remote plasma unit 165 may be used for multiple chambers, such as two, three, four, or more chambers up to all chambers for a particular quad section. Piping may extend from the remote plasma unit 165 to each aperture 160 for delivery of plasma effluents for processing or cleaning in embodiments of the present technology.

In some embodiments a purge channel 170 may extend through the transfer region housing proximate or near each substrate support 130. For example, a plurality of purge channels may extend through the transfer region housing to provide fluid access for a fluidly coupled purge gas to be delivered into the transfer region. The number of purge channels may be the same or different, including more or less, than the number of substrate supports within the processing system. For example, a purge channel 170 may extend through the transfer region housing beneath each substrate support. With the two substrate supports 130 illustrated, a first purge channel 170a may extend through the housing proximate substrate support 130a, and a second purge channel 170b may extend through the housing proximate substrate support 130b. It is to be understood that any additional substrate supports may similarly have a plumbed purge channel extending through the transfer region housing to provide a purge gas into the transfer region.

When purge gas is delivered through one or more of the purge channels, it may be similarly exhausted through pumping liners 145, which may provide all exhaust paths from the processing system. Consequently, in some embodiments both the processing precursors and the purge gases may be exhausted through the pumping liners. The purge gases may flow upwards to an associated pumping liner, for example purge gas flowed through purge channel 170b may be exhausted from the processing system from pumping liner 145b.

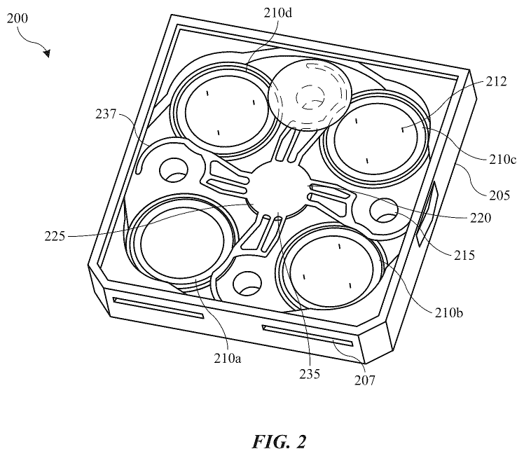

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region 120 described above, and may include any of the components or characteristics described. The system illustrated may include a transfer region housing 205 defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1A. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology.

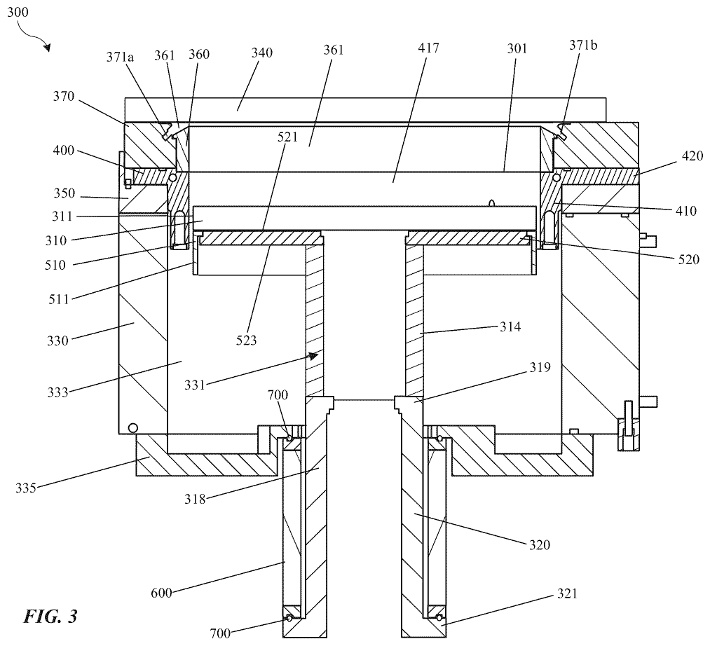

FIG. 3 shows a cross-sectional view of an exemplary substrate processing system 300 according to some embodiments of the present technology. FIG. 3 may illustrate further details relating to components in system 100 and/or 200, such as for choke plate 147. System 300 is understood to include any feature or aspect of system 100 and/or 200 discussed previously in some embodiments. The system 300 may be used to perform semiconductor processing operations including deposition of hardmask materials as previously described, as well as other deposition, removal, and cleaning operations. In particular, the substrate processing system 300 may include a transfer region housing (or chamber body) 330 (which may include a bottom plate 335 that defines a bottom of the chamber), outer isolator 510, inner isolator 520, pedestal 310, choke plate 400, lower lid plate 350, liner 360, faceplate 340, pumping liner 370, and/or a bellow 600 (among other components). The chamber body 330 may define a transfer region (or chamber volume) 333 therein for housing various components of the substrate processing system 300 during use. In particular, the chamber body 330 can house the pedestal 310, ground plate 380, and isolators 510,520,530 as they are vertically translated to a processing region, as discussed further below.

Pedestal or substrate support 310 may be disposed within the interior of the chamber body 330. The substrate support 310 may be vertically translatable within the chamber body 330 between the transfer region and the processing region. The substrate support 310 may include a support plate, which may include a heater an isolator, and/or other components. The substrate support 310 may also include a shaft 312 that may extend through a bottom of the chamber body 330. Shaft 312 may include a number of components, and may house various electronic connections, such as RF rods, heater rods, and the like, which may supply current to heaters, chucking electrodes, and/or a plasma electrode disposed within the support plate. In some embodiments, shaft 312 may include a ground shaft 314 and/or a shaft isolator. Ground shaft 314 may form an outermost layer of shaft 312 in some embodiments. Ground shaft 314 and shaft isolator may be formed from a dielectric material, such as alumina or other ceramic material in some embodiments. Ground shaft 314 may be supported atop a cooling hub 318, which may extend through an aperture formed in bottom plate 335. For example, a bottom surface of ground shaft 314 may be seated atop an upper flange 319 and/or other surface of cooling hub 318. In some embodiments, a top surface of the cooling hub 318 may define a number of dimples or other minimum contact features that protrude upward from the top surface to reduce the contact area and thermal transmission between the cooling hub 318 and the ground shaft 314. The dimples may have a height of between or about 0.05 mm and 0.5 mm, between or about 0.1 mm and 0.4 mm, between or about 0.15 mm and 0.3 mm, or between or about 0.2 mm and 0.25 mm, although other heights are possible in various embodiments. Any number of dimples may be provided, such as at least three dimples, at least four dimples, at least five dimples, at least six dimples, at least seven dimples, at least eight dimples, at least nine dimples, at least ten dimples, or more. The dimples may be spaced about the upper surface of cooling hub 318 at regular or irregular intervals.

Cooling hub 318 may include a collar portion 320 that extends downward from upper flange 319 and may terminate at a lower flange 321. Lower flange 321 may be coupled with a linear actuator (not shown) that may vertically translate cooling hub 318, shaft 331, and substrate support 310 within the chamber. In some embodiments, cooling hub 318 may be formed from a thermally conductive material, such as aluminum, which may enable the cooling hub 318 to create a thermal break below the heater of substrate support 310.

A bellow 600 may be coupled between the bottom plate 335 and the cooling hub 318. For example, a top end of bellow 600 may be coupled with a lower surface of bottom plate 335, while a bottom end of bellow 600 may be coupled with an upper surface of the lower flange 321. Bellow 600 may expand and contract as the substrate support 310 is translated within the chamber. For example, as the substrate support 310 is lowered, a greater portion of cooling hub 318 may extend below bottom plate 335. Since the top end of the bellow 600 is coupled with the fixed bottom plate 335, the upper end of the bellow 600 may remain stationary during the translation of the substrate support 310. As the cooling hub 318 is drawn further below bottom plate 335, the lower flange 321 pulls the lower end of bellow 600 downward, causing the bellow 600 to expand. Conversely, as the substrate support 310 is raised, a greater portion of cooling hub 318 may extend above bottom plate 335. Since the top end of the bellow 600 is coupled with the fixed bottom plate 335, the upper end of the bellow 600 may remain stationary during the translation of the substrate support 310. As the lower flange 321 of cooling hub 318 is drawn upward toward bottom plate 335, the lower flange 321 pulls the lower end of bellow 600 upward, causing the bellow 600 to contract. Bellow 600 may help prevent any process, purge, and/or cleaning gases from within the chamber environment from leaking out from the bottom of the chamber, such as through the aperture formed in bottom plate 335.

As will be discussed in greater detail below, the cooling hub 318, bellow 600, and bottom plate 335 may form a portion of an RF return path for system 300. To generate the connection between the components, a number of RF gaskets 700 may be provided that electrically couple adjacent components. For example, a bottom surface of bottom plate 335 may define a groove for receiving an RF gasket 700 that couples the bottom plate 335 with the bellow 600. In some embodiments, the top end of bellow 600 may define a corresponding groove for receiving the RF gasket 700. Similarly, the bottom end of the bellow 600 and/or a top surface of lower flange 321 of the cooling hub 318 may define a groove for receiving an RF gasket 700 that couples the bellow 600 with the cooling hub 318. Each RF gasket 700 may be formed from a combination of one or more polymeric materials and/or one or more conductive materials (such as metals).

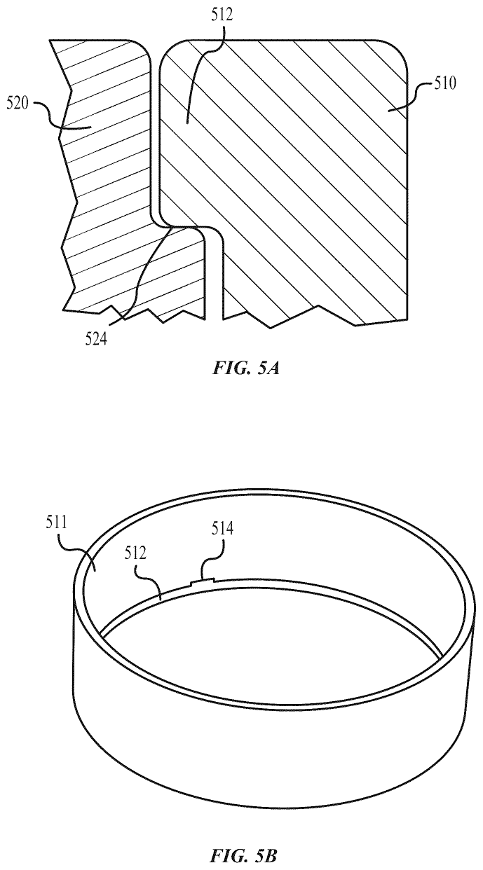

As noted above, system 300 may include inner isolator 520 and outer isolator 510, which may form part of and/or otherwise be coupled with substrate support 310 in some embodiments. In some embodiments, inner isolator 520 may be a substantially cylindrical disk and may be seated atop the ground shaft 314. Inner isolator 520 may have a top surface 521 and a bottom surface 523 and may define an aperture through both the top surface 521 and bottom surface 523. The aperture may be formed in a center of the inner isolator 520 in some embodiments. The aperture may enable a portion of shaft 331 through be inserted through the aperture. In some embodiments, top surface 521 may be seated against and/or otherwise proximate a bottom surface of the support plate of substrate support 310. As best illustrated in FIG. 5A, an outer edge of the inner isolator 520 may define a ledge 524, upon which outer isolator 510 may be seated. For example, outer isolator 510 may be a generally annular component that may define a central opening. A top end of outer isolator 510 may define a flange 512 or other protrusion that extends radially inward, with a bottom surface of flange 512 being seated atop ledge 524. In some embodiments, contact between inner isolator 520 and outer isolator 510 may be minimized, which may help reduce thermal expansion issues due to the isolators experiencing different temperatures during processing operations. For example, an inner surface of flange 512 and an outer surface of ledge 524 may be spaced apart from one another, such as by a distance of between or about 0.1 mm and 2 mm, between or about 0.2 mm and 1.5 mm, between or about 0.3 mm and 1 mm, or between or about 0.4 mm and 0.75 mm. Additionally or alternatively, one or both of the inner isolator 520 and the outer isolator 510 may define a number of minimum contact features that reduce a contact area between the two components. For example, as illustrated in FIG. 5B, a lower surface of flange 512 defines a number of protrusions 514 that extend downward. Protrusions 514 may contact the upper surface of ledge 524, while spacing apart the remaining lower surface of flange 512 from the upper surface of ledge 524. In some embodiments, each protrusion 514 may have a height of between or about 0.05 mm and 0.5 mm, between or about 0.1 mm and 0.4 mm, between or about 0.15 mm and 0.3 mm, or between or about 0.2 mm and 0.25 mm, although other heights are possible in various embodiments. Each protrusion 514 may have a length of between or about 5 mm and 100 mm, between or about 10 mm and 75 mm, between or about 15 mm and 50 mm, or between or about 20 mm and 30 mm, although other lengths are possible in various embodiments. Any number of protrusions 514 may be provided, such as at least three protrusions, at least four protrusions, at least five protrusions, at least six protrusions, at least seven protrusions, at least eight protrusions, at least nine protrusions, at least ten protrusions, or more. The protrusions 514 may be spaced about the flange 512 at regular or irregular intervals.

When seated atop inner isolator 520, outer isolator 510 may extend downward beyond a bottom surface of inner isolator 520. For example, a bottom end of the outer isolator 510 may extend downward along a portion of the length of the ground shaft 314 and may help further define a portion of a purge gas path as will be discussed in greater detail below.

In some embodiments, inner isolator 520 may define dimples extending outward from top surface 521. For example, with specific reference to FIG. 5, the inner isolator 520 may define dimples 522 extending out of the inner isolator 520 from the top surface 521. The dimples 522 may be arranged in various patterns, such as a number of annular rings, radial lines, and/or other symmetric or asymmetric patterns. Any number of dimples 522 may be used in various embodiments. For example, top surface 521 may have 25 or more dimples, 50 or more dimples, 100 or more dimples, 150 or more dimples, 200 or more dimples, 250 or more dimples, 300 or more dimples, 350 or more dimples, 400 or more dimples, 450 or more dimples, 500 or more dimples, or more. These dimples may act as minimum contact areas that reduce the heat transfer from a heated component of the substrate processing system (e.g., the heater of pedestal 310) and the components beneath the inner isolator 520 (e.g., the ground shaft 314 and cooling hub 318).

The dimples may have a height for optimally reducing the heat transfer from the heated component to the rest of the substrate processing system (e.g., to the ground shaft 314 and cooling hub 318) while still providing structural support to the heater and/or support plate of substrate support 310. For example, the dimples 522 may have a height ranging from between or about 0.05 mm and 0.70 mm, between or about 0.10 mm and 0.65 mm, between or about 0.15 mm and 0.60 mm, between or about 0.2 mm and 0.55 mm, or between or about 0.25 mm and 0.5 mm. Further, the dimples may have any combination of relative heights to optimize heat transfer reduction. For example, the dimples may all have the same height. Alternatively, the dimples may all have differing heights.

The inner isolators 520 and/or outer isolator 510 may be made of a material that minimizes heat transfer. For example, inner isolators 520 and/or outer isolator 510 may be made of a dielectric material, such as alumina or other ceramic material. The use of ceramic isolators 510,520 may address problems related to substrate contamination from contaminants coming from the substrate processing system. For example, conventional chamber designs may utilize a number of stainless steel components, which may oxidize in chamber environments. To prevent such oxidization, these components may be coated with chamber-compatible materials, such as aluminum and/or dielectric materials. However, such coatings may flake off or otherwise be damaged and may reveal the stainless steel material, leading to the oxidation of the underlying component. The oxidized stainless steel may form contaminants that have a risk of contaminating the substrates. The use of ceramic isolators (along with a ceramic ground shaft 314 and aluminum cooling hub 318) may help minimize the risk of this oxidation by eliminating the use of stainless steel components within the processing environment. Similarly, embodiments may omit the use of baffles within interior of the processing chamber (e.g., extending from a bottom of the substrate support 310 to a top surface of the bottom plate 335). The flexing of such baffles during translation of the substrate support 310 may cause residue and/or other particles that have deposited on the baffle to flake off. These flakes may cause fall on defects on wafer. Therefore, the elimination of the inner baffles may further improve the quality of wafers processed within the chamber.

Additionally, the isolators 510,520 may reduce the downward heat transfer coming from the heated substrate support 310 As noted above, RF current may be supplied to the substrate support 310 and/or one or more electrodes housed therein, thereby enabling the substrate support 310 and faceplate 340 to operate as companion electrodes for producing a capacitively coupled plasma within the processing region. The RF current may be supplied to the substrate support 310 via one or more RF rods that extend through the shaft 331. An RF current return path may be formed through faceplate 340, pumping liner 370, choke plate 400, lower lid plate 350, chamber body 330, bottom plate 335, bellow 600, cooling hub 318, and to an RF return rod within the shaft 331. To facilitate RF coupling of the components, interfaces between some or all adjacent components within the RF return path may include RF gaskets, such as RF gaskets 700. For example, RF gaskets 700 may be disposed between faceplate 340 and pumping liner 370, between pumping liner 370 and choke plate 400, between choke plate 400 and lower lid plate 350, between lower lid plate 350 and chamber body 330, between chamber body 330 and bottom plate 335, between bottom plate 335 and bellow 600, between bellow 600 and cooling hub 318, and/or between cooling hub 318 and an interior structure of shaft 331.

The substrate support 310 may be translatable within the chamber body 330 between a lower transfer region (illustrated here) and an upper processing region. During a processing operation, the substrate support 310 is moved upward within the chamber body 330 into a process position within the processing region. Once deposition and/or other processing operations are complete, the substrate support 310 may be lowered to a transfer position within the transfer region. The processed substrate may be removed from the substrate support 310 and a new substrate may be positioned atop the substrate support 310.

The stack of components seated on the chamber body 330 may define a processing region 301 overlying the chamber volume 333. For example, a top boundary of the processing region 301 may be defined by a bottom surface of the faceplate 340, a lower boundary of the processing region 301 may be defined by the pedestal 310, and lateral boundaries of the processing region 301 may be defined by inner surfaces of the lower lid plate 350, the liner 360, the pumping liner 370, and/or the choke plate 400. The lower lid plate 350 may be seated atop the chamber body 330 (either directly or indirectly).

The choke plate 400 may be seated on an upper surface of the lower lid plate 350. The choke plate 400 may be seated on the lower lid plate 350 on a first surface of the choke plate 400. The choke plate 400 may define a first aperture axially aligned the processing chamber and pedestal 310. The choke plate 400 may also define a second aperture axially aligned with an exhaust lumen formed in the chamber body 330 and/or pumping liner 370 that may form a portion of an exhaust channel to evacuate gases from the processing region 301. As illustrated, choke plate 400 may include a rim 410 defining the first aperture through the choke plate 400. The rim 410 may extend along a sidewall of the lower lid plate 350. In some embodiments a gap may be maintained between the rim 410 and the lower lid plate 350 to control heat flow between the components.

Rim 410 may extend vertically from the first surface of the choke plate 400 in a direction towards the lower lid plate 350 and may form a protrusion from the choke plate 400. The choke plate 400 may also include a flange 420 that extends laterally outward from the rim 410. For example, the flange 420 may extend outward from an outer surface of the rim 410 and may be seated atop the lower lid plate 350 in some embodiments. In a particular embodiment, the flange 420 and the rim 410 may share a single first surface such that the flange 420 is positioned at a top end of the choke plate 400, although other positions of the flange 420 relative to the rim 410 are possible. The rim 410 may include a distal end 401. The distal end 401 may be the bottom-most end of the choke plate 400 such that, when the choke plate 400 is assembled in the substrate processing system 300, the end 401 is the portion of the choke plate 400 that extends farthest into the chamber volume 333.

The liner 360 and pumping liner 370 may be seated atop the choke plate 400, such as atop the first surface of the choke plate 400. The liner 360 may have a top edge shorter than a top edge of the pumping liner 370 such that there is a vertical gap 361 between the liner 360 and the pumping liner 370. The vertical gap 361 may enable one or more gases to exhausted from the processing region 301 via one outlets 371a,b that are defined in a surface of the pumping liner 370. Gases exhausted via the pumping liner 370 may be passed through apertures defined by the choke plate 400 and chamber body 330 that are radially outward of the processing region.

An inner surface of the liner 360 and an inner surface of the choke plate 400 may be aligned flush with each other such that the inner surfaces define a substantially uniform diffusion surface. For example, the inner surfaces may have substantially the same circumference and be concentric with each other to define the smooth surface. This smooth surface allows for purge gas to uniformly flow along the surface without running into irregularities that would otherwise roughen the flow of purge gas, thus allowing for a more uniform and consistent diffusion of purge gas toward the faceplate 340. This increased uniformity and consistency, in turn, allows for a decreased flow rate for the purge gas to purge the faceplate 340 and other proximate components, and may help prevent sublimation. Similarly, an outer surface 311 of the pedestal 310 and an outer surface of the outer isolator 511 may be aligned flush with each other such that the outer surface 311 and the outer surface of the outer isolator 511 define a substantially smooth and uniform diffusion surface between the pedestal 310 and the chamber walls. For example, the outer surface 311 and the outer surface of the outer isolator 511 may have substantially the same circumference and be concentric with each other to define the smooth surface. This smooth surface achieves a similar result as discussed above for the uniform surface of the inner surfaces. Therefore, the smooth surface of the inner surfaces and the smooth surface of the outer surfaces 311,511 define, between them, a portion of the processing purge flow path that has substantially no interfering protrusions to inhibit purge gas flow. The purge gas may flow between these surfaces uniformly and allow for maximal transfer of flow rate towards the faceplate 340.

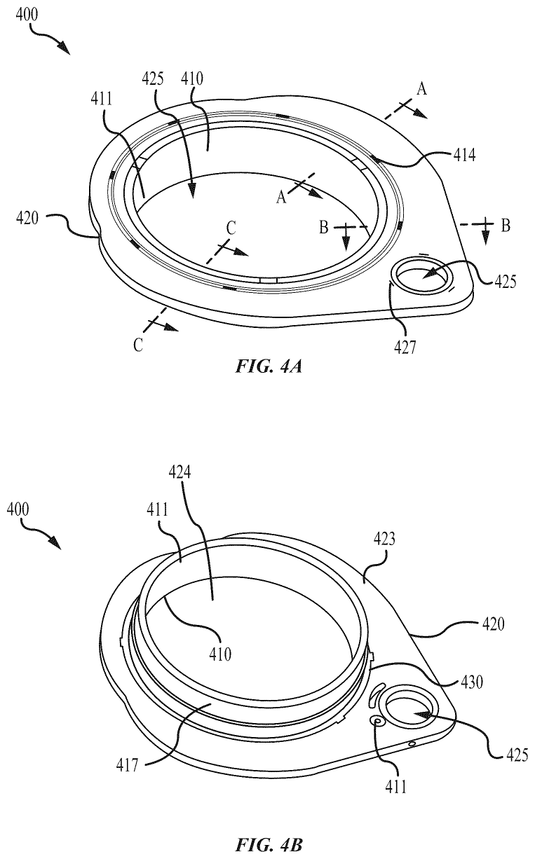

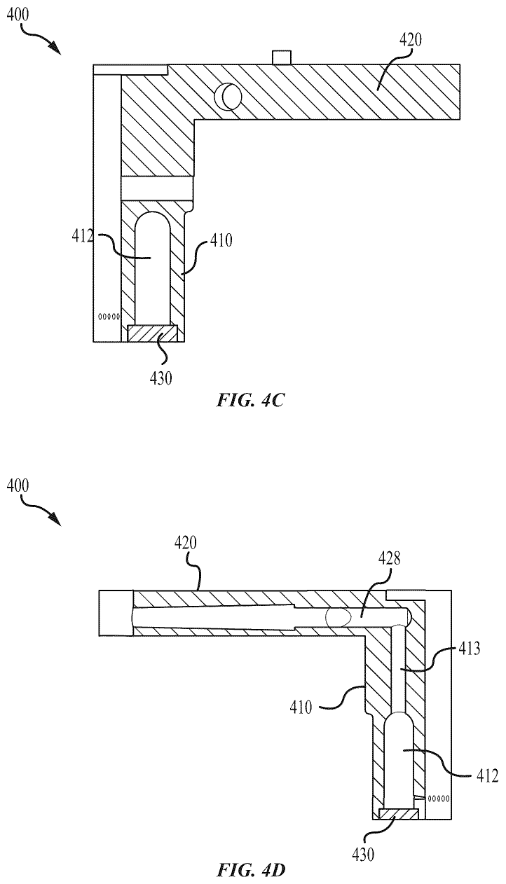

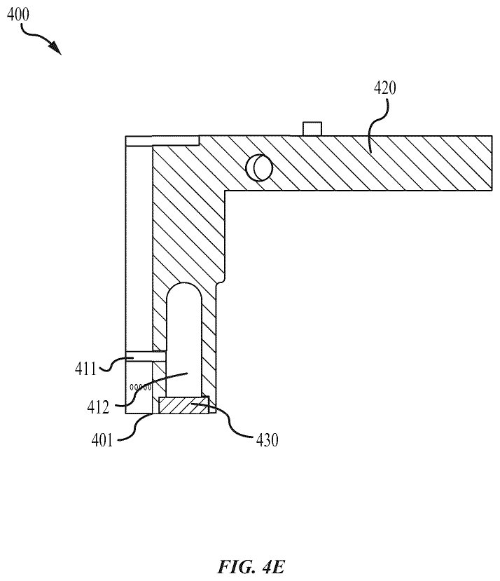

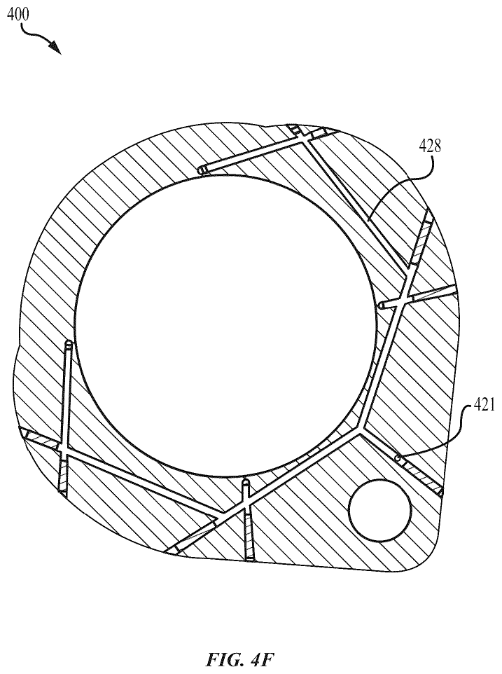

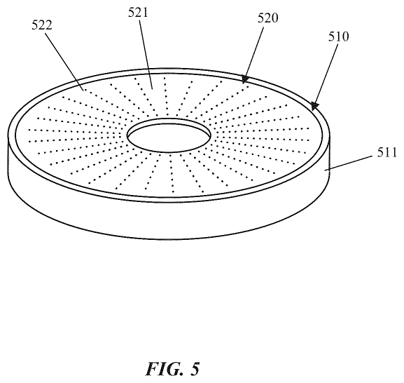

FIGS. 4A-4F show the choke plate 400. As discussed above for choke plate 147, the choke plate 400 may be used to control heat transfer through a chamber in the substrate processing system (e.g., the chamber body 330). As illustrated, choke plate 400 may be or include a thermally conductive plate defining a first aperture 424 through the plate, and a second aperture 425 through the plate. The second aperture 425 may be laterally offset on the choke plate 400 from the first aperture 424. The geometry of the choke plate 400 may be provided to accommodate the structure of the lid plate on which the choke plate 400 may be seated (such as lower lid plate 350). In a particular embodiment, an outer periphery of the choke plate 400 may be generally tear drop-shaped. For example, the outer periphery may include a small arc-shaped segment that is joined with a larger arc-shaped segment via two generally linear segments. The second aperture 425 may be coaxial with the small arc-shaped segment, while the first aperture 424 may be coaxial with the larger arc-shaped segment.

The choke plate 400 may define a number of minimum contact features (such as protrusions) may be formed on the top surface of the choke plate 400 and/or the bottom surface of the pumping liner 370 to help minimize contact and thermal transfer between the components. As illustrated in FIG. 4A, a top surface 422 of the choke plate 400 defines a number of protrusions 414 that serve as minimum contact features to reduce the contact area between the choke plate 400 and the pumping liner 370. In some embodiments, each protrusion 414 may have a height of between or about 0.05 mm and 0.5 mm, between or about 0.1 mm and 0.4 mm, between or about 0.15 mm and 0.3 mm, or between or about 0.2 mm and 0.25 mm, although other heights are possible in various embodiments. Each protrusion 414 may have a length of between or about 5 mm and 100 mm, between or about 10 mm and 75 mm, between or about 15 mm and 50 mm, or between or about 20 mm and 30 mm, although other lengths are possible in various embodiments. Any number of protrusions 414 may be provided, such as at least three protrusions, at least four protrusions, at least five protrusions, at least six protrusions, at least seven protrusions, at least eight protrusions, at least nine protrusions, at least ten protrusions, or more. The protrusions 414 may be spaced apart at regular (or substantially regular) intervals about the first aperture 424. As used herein, substantially regular intervals may be understood to mean that an angular spacing between any two adjacent protrusions may be within or about 10 degrees of an average angular spacing between adjacent protrusions of the choke plate 400, within or about 5 degrees of the average angular spacing, within or about 4 degrees of the average angular spacing, within or about 3 degrees of the average angular spacing, within or about 2 degrees of the average angular spacing, within or about 1 degree of the average angular spacing, or less.

Although eight protrusions 414 are illustrated, it is to be understood that any number of protrusions 414 may be included in embodiments of the present technology. For example, the choke plate 400 may include at least or about four protrusions 414, at least or about five protrusions 414, at least or about six protrusions 414, at least or about seven protrusions 414, at least or about eight protrusions 414, at least or about nine protrusions 414, at least or about 10 protrusions 414, at least or about 12 protrusions 414, at least or about 14 protrusions 414, or more. A width (e.g., a distance between an inner edge and an outer edge of each protrusion 414) of each protrusion 414 may be between or about 1 mm and 10 mm, between or about 2 mm and 9 mm, between or about 3 mm and 8 mm, or between or about 4 mm and 7 mm. Typically, each of the protrusions 414 has a same set of dimensions, although some embodiments may incorporate one or more protrusions 414 with different dimensions.

Choke plate 400 may define a number of protrusions 427 that extend from the first surface of the choke plate 400 (e.g., along flange 420), with the protrusions 427 being distributed radially about the second aperture 425 as illustrated. For example, the protrusions 427 may be distributed in a generally symmetric arrangement about the second aperture 425. The protrusions 427 may be spaced apart at regular (or substantially regular) intervals about the second aperture 425. Although three protrusions 427 are illustrated, it is to be understood that any number of protrusions 427 may be included in embodiments of the present technology. For example, the choke plate 400 may include at least or about three protrusions 427, at least or about four protrusions 427, at least or about five protrusions 427, or more. Each protrusion 427 may project outward from the first surface of the choke plate 400 by between or about 0.05 mm and 0.50 mm, between or about 0.10 mm and 0.40 mm, between or about 0.15 mm and 0.30 mm, or about 0.20 mm. Oftentimes, protrusions 427 may project outward from the first surface by a same or substantially same (e.g., within or about 10%, within or about 5%, within or about 3%, within or about 1%) distance as protrusions 426. Protrusions 427 may be arcuate segments, however a length of each protrusion 427 may be sufficiently small that each protrusion 427 may be nearly rectangular in shape. Each protrusion 427 may have a length or average length (e.g., average of a length of an inner edge and an outer edge of each protrusion 427) of between or about 5 mm and 30 mm, between or about 10 mm and 20 mm, or about 15 mm. A width (e.g., a distance between an inner edge and an outer edge of each protrusion 427) of each protrusion 427 may be between or about 1 mm and 8 mm, between or about 1.5 mm and 6 mm, or between or about 2 mm and 4 mm. Typically, each of the protrusions 427 has a same set of dimensions, although some embodiments may incorporate one or more protrusions 427 with different dimensions. The protrusions 414,427 may help provide a minimum contact area that limits contact between the choke plate 400 and a component seated atop the choke plate 400 (e.g., pumping liner 370).

While not illustrated, a lower surface of the flange 420 may include a similar set of protrusions about each of the first aperture 424 and second aperture 425. By incorporating an arrangement of the various protrusions about the first aperture 424 and second aperture 425, embodiments of the present technology may enable deformation of the choke plate 400 to be more uniform when under high vacuum loads. This even deformation may ensure that heat transfer through the choke plate 400 is uniform and may help improve the temperature uniformity of the faceplate. Additionally, by keeping the protrusions small in size contact between the choke plate 400 and the pumping liner 370 and between the choke plate 400 and the lower lid plate 350 is minimized, which limits heat transfer through the choke plate 400 and helps thermally isolate the pumping liner 370 and faceplate 340 from the colder, unheated lower lid plate 350.

In some embodiments, the choke plate 400 (and/or rim 410) may have a thickness (or height) from the first surface (e.g., top surface 422 of the rim 410 and flange 420) to a second surface (e.g., lower surface of rim 410) of between about 70 mm and 100 mm, between about 75 mm and 95 mm, between about 80 and 90 mm, or about 85 mm. In some embodiments, a thickness of the flange 420 may be between about 10 mm and 25 mm or between about 15 mm and 20 mm. Such dimensioning may enable the lower surface of rim 410 to protrude downward from the lower surface of the flange 420 by between about 45 mm and 90 mm, between about 50 mm and 85 mm, between about 55 mm and 80 mm, between about 60 mm and 75 mm, or between about 65 mm and 70 mm. This distance may help increase a diffusion distance of the chamber and may help reduce the amount of purge gas that must be flowed into the chamber during processing operations to keep the chamber components free of film residue.

The flange 420 includes top surface 422 and a bottom surface 423. The flange 420 may define a purging inlet 421 through a peripheral or lateral surface that extends between top surface 422 and bottom surface 423, the purging inlet 421 designed for introducing a purge gas to an interior of the choke plate 400. However, in other embodiments, the purging inlet may be defined through top surface 422 of the flange 420 and/or through bottom surface 423 of the flange 420. The rim 410 may define a plurality of purging outlets 411 that may be fluidly coupled with the purging inlet 421 to deliver a purge gas into an interior of the first aperture 424 (and processing region 301). The purging outlets 411 may be positioned in one or more rows at one or more vertical positions of the rim 410. For example, some or all of the purging outlets 411 may be positioned within an upper 25% of the rim 410, some or all of the purging outlets 411 may be positioned within an upper middle 25% of the rim 410, some or all of the purging outlets 411 may be positioned within a lower middle 25% of the rim 410, some or all of the purging outlets 411 may be positioned within an lower 25% of the rim 410, or other position about the rim 410.

In one example, there may be one-hundred and eighty purging outlets to allow for uniform distribution of gas exiting the purging outlets. However, in other embodiments, there may be more or less than one-hundred and eighty purging outlets. For example, there may be at least or about 40 purging outlets, at least or about 60 purging outlets, at least or about 80 purging outlets, at least or about 100 purging outlets, at least or about 120 purging outlets, at least or about 140 purging outlets, at least or about 160 purging outlets, at least or about 180 purging outlets, at least or about 200 purging outlets, at least or about 220 purging outlets, at least or about 240 purging outlets, or more. The purging outlets 411 may be formed at regular intervals and/or irregular intervals about the inner surface of the rim 410. Each purging outlet 411 may have a same diameter, or some or all of the purging outlets 411 may have different diameters from one another.

With specific reference to FIGS. 4C and 4D, the flange 420 may define a purge channel 428 through the flange 420 in communication with, and extending from, the purging inlet 421 towards the rim 410 to form a part of the purge flow path. The purge channel 428 may be formed from one or more segments of lumens that fluidly couple with the purging inlet 421 and extend at least partially about first aperture 424. For example, in some embodiments, the purge channel 428 may include an annular and/or C-shaped segment that extends about first aperture 424 and a linear segment that extends between and fluidly couples the purging inlet 421 and the annular and/or C-shaped segment. In other embodiments, such as illustrated in FIG. 4F, the purge channel 428 may be formed by gun drilling, such as by forming a number of linear segments at various angles. For example, a number of angled linear segments may be drilled or otherwise formed through the choke plate 400 to extend to a number of baffle hole locations (as will be discussed below). As illustrated, there are four baffle hole locations, each extending from one linear segment. Two or more additional linear segments may be formed to couple the four (or other number) angled linear segments extending from the baffle hole locations. An additional linear segment may extend from the purging inlet 421 and fluidly couple with the various angled linear segments to form a purge path from the purging inlet 421 to the various baffle hole locations.

The purge channel 428 may be fluidly coupled with a plenum 412 positioned in vertical alignment with some or all of the purging outlets 411. Plenum 412 may extend about the entire or substantially all of the circumference of the rim 410. For example, plenum 412 may be generally annular or C-shaped. Plenum 412 may be aligned with and fluidly coupled with each of the purging outlets 411, which may deliver the purge gas to the interior of the first aperture 424.

The rim 410 may define one or more baffle holes 413 (with one at each baffle hole location) that extend between and fluidly couple the purge channel 428 plenum 412. This may enable purge gas flowing in purge channel 428 to flow into the plenum 412 at one or more locations about the periphery of the first aperture 424. Although FIG. 4D depicts only one baffle hole 413, the choke plate 400 may define any number of baffle holes (not shown) at different radial positions about the first aperture 424 to at least substantially distribute the purge gas about a circumference of the plenum 412. Any number of baffle holes 413 may be present in choke plate 400. For example, choke plate 400 may include one or more baffle holes, two or more baffle holes, three or more baffle holes, four or more baffle holes, five or more baffle holes, six or more baffle holes, eight or more baffle holes, ten or more baffle holes, or more. Each of the baffle holes 413 may have a same or different diameter and/or cross-sectional area. For example, some or all of the baffle holes 413 may have different diameters and/or cross-sectional area to account for the proximity of the baffle holes to the purging inlet 421. In particular, one or more baffle holes closer to the purging inlet 421 may have a smaller diameter and/or cross-sectional area to account for purge gas filling up the portion of the plenum 412 closer to the purging inlet 421 faster than the portion of the plenum 412 further from the purging inlet 421. This difference in diameter and/or cross-sectional area allows for the purge gas to fill up the plenum 412 in a substantially uniform manner. This configuration allows for the purge gas to uniformly exit the choke plate 400 to provide an even distribution of gas into the substrate processing system. The diameters of the baffle holes 413 may often be between about 3 mm and 15 mm, between about 4 mm and 13 mm, between about 5 mm and 11 mm, or between about 6 mm and 10 mm, although other diameters are possible in various embodiments.

In one example, there may be four total baffle holes 413, where the two baffle holes 413 closest to the purging inlet 421 may have a circumferential width of 6 mm and where the two baffle holes 413 farthest from the purging inlet may have a circumferential width of 10 mm. However, in other examples, there may be any number of baffle holes 413. Further, each of the baffle holes 413 may have any diameter and/or cross-sectional area to allow for uniform distribution of gas into the plenum 412. In one alternative, there may be a single baffle hole 413 (such as an annular or arc-shaped baffle hole), with the single baffle hole having a cross-sectional area along its circumference (e.g., a smaller width closer to the purging inlet 421 and a larger width farther from the purging inlet 421) to account for the position of the purging inlet 421. In a further alternative, there may be one or more baffle holes 413 having a substantially equal width and the rim 410 defines the plenum 412 to have differing volumes along its circumference (e.g., a larger volume for the portions of the plenum 412 closer to the purging inlet 421 and a smaller volume for the portions of plenum 412 farther from the purging inlet 421) to account for the position of the purging inlet 421.

In some embodiments, the choke plate 400 may additionally include one or more closing plates 430 secured to the choke plate 400 through any means known in the art (e.g., welding or the like). Each closing plate 430 may be used to seal off the plenum and/or baffle holes upon being machined and/or otherwise formed into a surface of the rim 410.

The choke plate 400 may address problems related to faceplate sublimation faced by prior substrate processing systems. In traditional designs of substrate processing systems, purge gas is expelled from the bottom of the chamber body to clean the processing region. However, the flow rate required to purge the processing region when purge gas comes from the bottom of the chamber body was too high in prior designs.

The choke plate 400 may solve this issue by introducing the purge gas closer to the pedestal 310 and faceplate 340, which may decrease the flow rate of purge gas required to purge the processing region as the purge gas now exits the purging outlets 411. This decreased distance thus allows for the faceplate 340 to be properly purged with lower volumes of purge gas and to prevent sublimation across its face with a decreased amount of purge flow rate than what was previously required.

Additionally, when the purge gas comes from below, the purge gas may blow contaminants that are formed within the chamber body into the processing region 301. Moving the purge gas from the bottom of the chamber body to the choke plate 400 reduces the risk of such contamination as the purging outlets 411 are now much closer to the processing region 301. Moreover, by moving the purge gas introduction upward into a reactor volume of the chamber, the pressure differences between the reactor volume and shared transfer volumes in multi-chamber systems may be reduced. The temperature uniformity during hot-leveling of the pedestal 310 may also be improved. Additionally, when coupled with the chamber configurations that do not include stainless steel components within the processing volume, embodiments may further reduce the occurrence of fall on defects on wafer, such as those caused by oxidation of stainless steel components within the purge path.

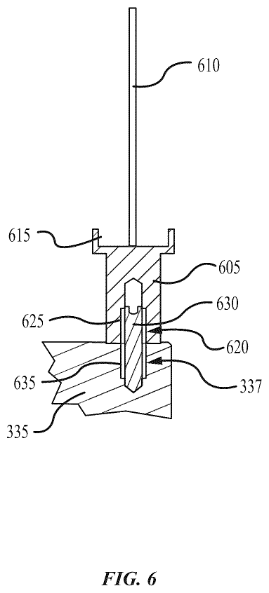

In some embodiments, to further reduce or eliminate the presence of stainless steel within the chamber environment, a lift pin assembly may be modified. As illustrated in FIG. 6 each lift pin assembly (which may be utilized in system 100, 200, 300, or any other substrate processing system, and may be aligned with corresponding lift pin apertures formed through the substrate support 310) may include a standoff 605 that may be mounted or otherwise coupled with the bottom plate 335 and/or other structural component positioned beneath the support plate of the substrate support 310. The standoff 605 may support a lift pin 610, which may be seated within a recess 615 formed in a top end of the standoff 605. Each lift pin 610 may protrude upward to enable a top end of the lift pin 610 to extend beyond an upper surface of the substrate support 310 when the substrate support 310 is in a transfer position. This enables a transfer apparatus to transfer substrates to and from the lift pins 610. Raising the substrate support 310 may enable the substrates to be lowered from the lift pins 610 to the substate support surface of the substrate support 310.

Standoff 605 may be formed from aluminum and/or another chamber-compatible material (e.g., not stainless steel). To facilitate the coupling of the aluminum standoff 605 with the bottom plate 335, a bottom end of standoff 605 may define a central bore 620. Central bore 620 may receive an insert 625, which may be secured within central bore 620 using threads, press fit, and/or other securement technique. Insert 625 may include internal threads that may enable a threaded stud 630 to be secured within the insert 625. Threaded stud 630 may have external threads that engage with the internal threads of insert 625. Bottom plate 335 may define a recess 337 that may be sized to receive an additional insert 635, which may be similar to insert 625. Insert 635 may be secured within recess 337 using threads, press fit, and/or other securement technique. Insert 635 may include internal threads that may enable threaded stud 630 to be secured within the insert 625 to couple the standoff 605 with bottom plate 335. The inserts 625, 635 and/or threaded stud 630 may be formed from a harder material than standoff 605 and/or bottom plate 335. For example, inserts 625, 635 and/or threaded stud 630 may be formed from stainless steel or other hard alloy. As the inserts 625, 635 and threaded stud 630 are entirely encapsulated by bottom plate 335 and standoff 605, the stainless steel or other material is not exposed to the chamber environment, and therefore poses little to no risk of oxidizing and creating undesired particles within the processing chamber.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a chamber body comprising a bottom plate;
a substrate support disposed within the chamber body, the substrate support comprising a support plate and a shaft, wherein the shaft comprises:
a cooling hub that extends through the bottom plate; and
a ground shaft that is seated atop the cooling hub, the ground shaft comprising a ceramic material;
an inner isolator coupled with a bottom of the support plate, the inner isolator defining an aperture therethrough that receives the shaft; and
an outer isolator that is seated atop the inner isolator, wherein each of the inner isolator and the outer isolator comprises a ceramic material.

2. The semiconductor processing system of claim 1, further comprising:
a lower lid plate seated atop the chamber body.

3. The semiconductor processing system of claim 2, further comprising:
a thermal choke plate seated atop the lower lid plate.

4. The semiconductor processing system of claim 3, further comprising:
a pumping liner seated atop the thermal choke plate.

5. The semiconductor processing system of claim 4, further comprising:
a faceplate seated atop the pumping liner, the faceplate defining a processing region from above.

6. The semiconductor processing system of claim 5, further comprising:
a bellow that couples a bottom surface of the bottom plate with a bottom end of the cooling hub.

7. The semiconductor processing system of claim 6, wherein:
the faceplate, the pumping liner, the thermal choke plate, the lower lid plate, the chamber body, the bottom plate, the bellow, and the cooling hub form a portion of an RF return path.

8. The semiconductor processing system of claim 7, further comprising:
a plurality of RF gaskets, each of the plurality of RF gaskets being disposed between two adjacent components that make up the RF return path.

9. The semiconductor processing system of claim 3, wherein:
the thermal choke plate defines a purge inlet, a purge channel, and a number of purge outlets that deliver a purge gas to an interior of the chamber body.

10. The semiconductor processing system of claim 1, wherein:
there is no exposed stainless steel within an interior of the chamber body.

11. A semiconductor processing system, comprising:
a chamber body comprising a bottom plate;
a substrate support disposed within the chamber body, the substrate support comprising a support plate and a shaft, wherein the shaft comprises:
a cooling hub that extends through the bottom plate, wherein a top surface of the cooling hub defines a plurality of dimples; and
a ground shaft that is seated atop the plurality of dimples, the ground shaft comprising a ceramic material;
an inner isolator coupled with a bottom of the support plate, the inner isolator defining an aperture therethrough that receives the shaft; and
an outer isolator that is seated atop the inner isolator, wherein each of the inner isolator and the outer isolator comprises a ceramic material.

12. The semiconductor processing system of claim 11, further comprising:
a plurality of lift pin assemblies, each lift pin assembly comprising:
a standoff that is seated atop the bottom plate, the standoff comprising a chamber-compatible material; and
a lift pin seated atop the standoff.

13. The semiconductor processing system of claim 12, wherein:
the chamber-compatible material comprises aluminum.

14. The semiconductor processing system of claim 12, wherein:
a bottom end the standoff defines a central bore;
the bottom plate defines a recess;
a first insert is received within the central bore;
a second insert is received within the recess; and
a threaded stud is inserted within both the first insert and the second insert to secure the standoff to the bottom plate.

15. The semiconductor processing system of claim 14, wherein:
the first insert, the second insert, and the threaded stud comprise stainless steel.

16. The semiconductor processing system of claim 11, further comprising:
a thermal choke plate seated atop the chamber body, the thermal choke plate defining a purge inlet, a purge channel, and a number of purge outlets that deliver a purge gas to an interior of the chamber body.

17. The semiconductor processing system of claim 16, wherein:
the purge channel comprises a number of linear segments that intersect one another.

18. A semiconductor processing system, comprising:
a chamber body comprising a bottom plate;
a substrate support disposed within the chamber body, the substrate support comprising a support plate and a shaft, wherein the shaft comprises:
a cooling hub that extends through the bottom plate; and
a ground shaft that is seated atop the cooling hub, the ground shaft comprising a ceramic material;
a bellow that couples a bottom surface of the bottom plate with a bottom end of the cooling hub;
an inner isolator coupled with a bottom of the support plate, the inner isolator defining an aperture therethrough that receives the shaft; and
an outer isolator that is seated atop the inner isolator, wherein each of the inner isolator and the outer isolator comprises a ceramic material.

19. The semiconductor processing system of claim 18, wherein:
a bottom end of the cooling hub comprises a lower flange;
an upper end of the bellow is coupled with the bottom surface of the bottom plate;
a lower end of the bellow is coupled with an upper surface of the lower flange; and
the bellow expands and contracts as the substrate support is translated within the chamber body.

20. The semiconductor processing system of claim 19, further comprising:
a first RF gasket disposed between the bottom surface of the bottom plate and the upper end of the bellow; and
a second RF gasket disposed between the lower end of the bellow and the upper surface of the lower flange.
